(19) United States
(12) Patent Application Publication
(10) Pub. No.: US 2015/0271962 A1
(43) Pub. Date: Sep. 24, 2015

(54) CIRCUIT BOARD SUCTION ASSEMBLY

(71) Applicant: Quik-Tool LLC, Plainville, MA (US)

(72) Inventor: Charles Moncavage, Nazareth, PA (US)

(73) Assignee: QUIK-TOOL LLC, Plainville, MA (US)

(21) Appl. No.: 14/664,817

(22) Filed: Mar. 21, 2015

Related U.S. Application Data
(60) Provisional application No. 61/969,120, filed on Mar. 22, 2014.

(51) Int. Cl. H05K 13/00; H05K 3/00; B25B 11/00

(52) U.S. Cl. CPC H05K 13/0069; B25B 11/005; H05K 3/00; H05K 2203/0165

(57) ABSTRACT

A circuit board suction assembly device includes a body having a vacuum connection side and a rail engagement side, disposed opposite the vacuum connection side. A board engagement face is disposed between the vacuum connection side and a rail engagement side. The board engagement face includes at least one suction cup extending outwardly therefrom. A method of securing a circuit board onto the circuit board suction assembly device is also provided.

### CROSS-SECTION REFERENCE TO RELATED APPLICATION

The present application claims priority from U.S. Provisional Patent Application Ser. No. 61/969,120, filed on Mar. 22, 2014, which is incorporated by reference herein in its entirety.

### BACKGROUND OF THE INVENTION

Electronic circuit boards are typically manufactured by transporting a planar board on a conveyor, placing a stencil over the board and applying solder paste over the stencil, with paste extending through holes or openings in the stencil and onto the board. Additionally, components, such as, for example, resistors, capacitors, diodes, etc., are attached to the board after the solder paste is applied. Due to the small nature of the components, as well as the desire to compact the components on the board to reduce the size of the board, tolerances can be critical. In particular, it can be critical that the board extends in a flat plane so that the solder paste and components were applied in proper locations on the board. Occasionally, however, a board may have a slight defect, such as a warp, that may result in improper placement of the solder paste and/or components. Such a board is not useful and must be discarded. It would be beneficial to provide a mechanism that ensures that, during the solder and component applying processes, the board is flat.

### BRIEF SUMMARY OF THE PRESENT INVENTION

Briefly, the present invention provides a circuit board suction assembly device comprising a body having a vacuum connection side and a rail engagement side, disposed opposite the vacuum connection side. A board engagement face is disposed between the vacuum connection side and a rail engagement side. The board engagement face includes at least one suction cup extending outwardly therefrom.

The present invention also provides a method of securing a circuit board to the circuit board suction assembly device described above.

Further, the present invention also provides a circuit board suction assembly device comprising a body having a first sidewall extending downwardly from the body and a second sidewall, opposite the first sidewall. The second sidewall extends outwardly from the body. A board engagement face is disposed on a top surface of the body between the first sidewall and the second sidewall. The board engagement face comprises at least one suction cup extending outwardly therefrom. A vacuum face is disposed between the first sidewall and the second sidewall.

### BRIEF DESCRIPTION OF THE DRAWINGS

The accompanying drawings, which are incorporated herein and constitute part of this specification, illustrate the presently preferred embodiments of the invention, and, together with the general description given above and the detailed description given below, serve to explain the features of the invention. In the drawings:

FIG. 1 is a perspective view of an exemplary embodiment of the inventive assembly used with an existing printed circuit board manufacturing machine;

FIG. 2 is a top plan view of the existing printed circuit board manufacturing machine of FIG. 1, prior to aligning the inventive assembly with a circuit board;

FIG. 3 is a sectional view of the inventive assembly, taken along lines 3-3 of FIG. 2;

FIG. 4 is a top plan view of the existing printed circuit board manufacturing machine of FIG. 1, after aligning the inventive assembly with a circuit board;

FIG. 5 is a side perspective view of a portion of the existing printed circuit board manufacturing machine of FIG. 1, taken along lines 5-5 of FIG. 2, with the inventive assembly in a pre-vacuum condition;

FIG. 6 is a side perspective view of a portion of the existing printed circuit board manufacturing machine of FIG. 1, taken along lines 6-6 of FIG. 4, with the inventive assembly in a vacuum condition;

FIG. 7 is a sectional view of an alternative embodiment of the inventive assembly in a pre-vacuum condition;

FIG. 8 is a sectional view of the inventive assembly of FIG. 7 in a vacuum condition;

FIG. 9 is a side elevational view of an alternative embodiment of the inventive assembly used with an existing printed circuit board manufacturing machine;

FIG. 10 is a rear elevational view of the inventive assembly shown in FIG. 9;

FIG. 11 is a top plan view of the inventive assembly shown in FIG. 9;

FIG. 12 is a side elevational view of a board flattening device according to an exemplary embodiment of the present invention; and

FIG. 13 is a front elevational view of the board flattening device shown in FIG. 12.

### DETAILED DESCRIPTION OF THE INVENTION

In the drawings, like numerals indicate like elements throughout. Certain terminology is used herein for convenience only and is not to be taken as a limitation on the present invention. The terminology includes the words specifically mentioned, derivatives thereof and words of similar import. The embodiments illustrated below are not intended to be exhaustive or to limit the invention to the precise form disclosed. These embodiments are chosen and described to best explain the principle of the invention and its application and practical use and to enable others skilled in the art to best utilize the invention.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Referring to the Figures in general, a suction assembly 100 according to a first exemplary embodiment of the present invention is shown. Suction assembly 100 can be used to secure a printed circuit board 50 to a board assembly machine 60 during manufacture of board 50. The mechanism of using a suction to secure board 50 to board assembly machine 60 “flattens” board 50 so that board 50 extends in a flat plane. As a result, assembly of components (not shown) onto board 50 can be accurately performed.

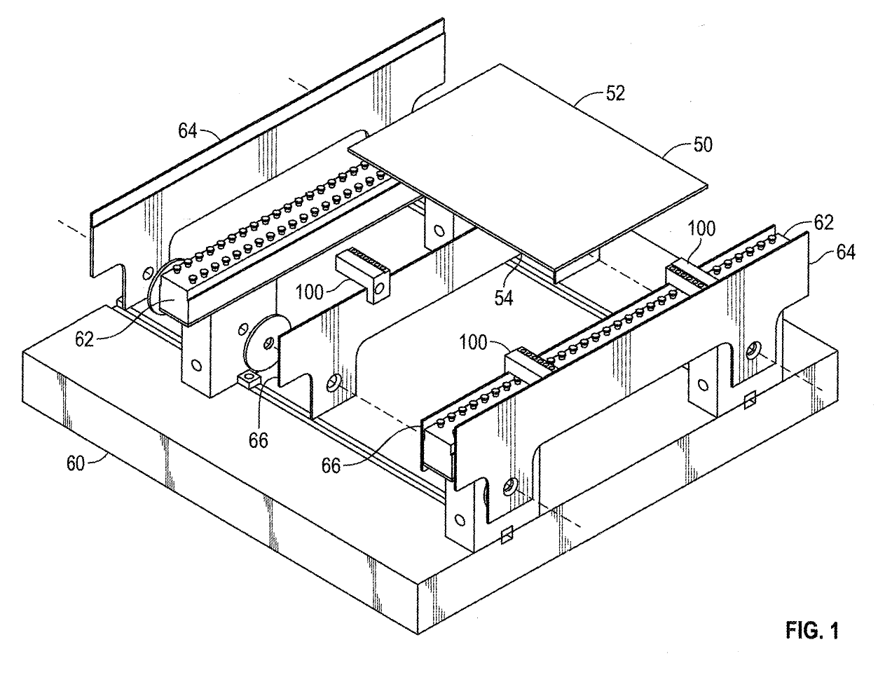

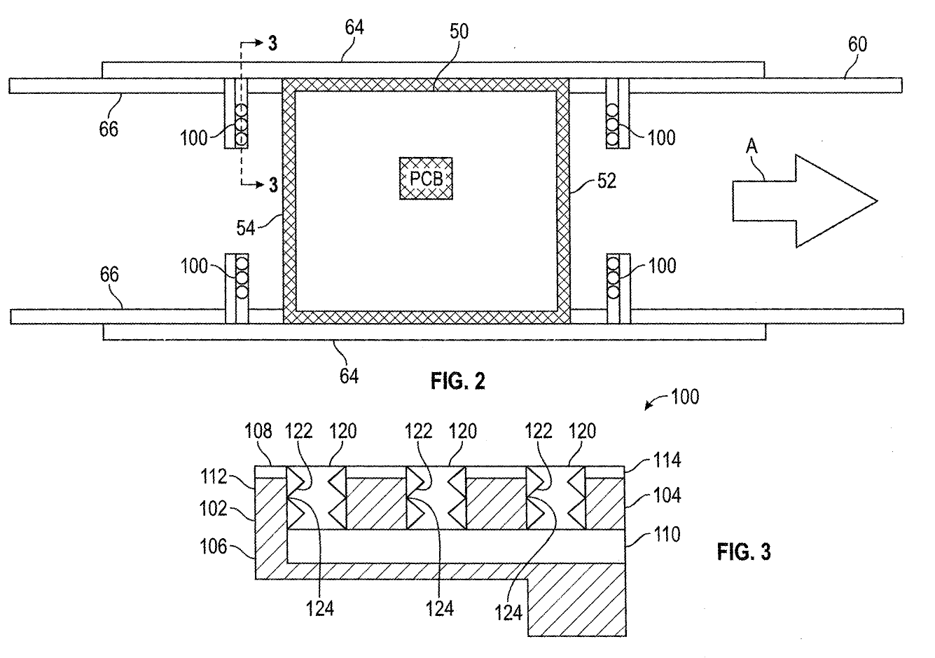

Referring to FIGS. 1 and 2, the work station portion of a board assembly machine 60 that can be used with the present invention is shown. Those skilled in the art, however, will recognize that other board assembly machines can be used. Typically, in this location, solder (not shown) is applied to the top surface of board 50, although those skilled in the art will recognize that other operations can be performed on board 50.

In an exemplary embodiment, board supports 62 can be incorporated into board assembly machine 60. Board supports 62 support board 50 on board assembly machine 60 during the manufacture process. Exemplary board supports can be the supports manufactured by Quik-Tool, LLC of Plainville, Mass., which is the owner of the present invention. Those skilled in the art, however will recognize that board supports 62 can be omitted and not defeat the scope of this invention. Board assembly machine 60 also includes support rails 64 on which an edge of board 50 rides. Further, board assembly machine 60 also includes a suction support rail 66 on which suction assembly 100 rides. As shown in FIG. 1, two suction support rails 66 are used, with one suction support rail 66 being disposed on either side of board assembly machine 60. Each suction support rail 66 supports two suction assemblies 100 for a total of four suction assemblies 100 being used to support one board 50. Each suction assembly 100 is located proximate to a corner of board 50. While four suction assemblies 100 are shown, those skilled in the art will recognize that, for larger circuit boards 50, additional assemblies 100 (not shown) can be spaced around the perimeter of board 50 to provide additional support.

Referring to FIG. 3, suction assembly 100 includes a generally parallelepiped body 102 having a vacuum connection side 104, a rail engagement side 106, disposed opposite the vacuum connection side 104, and a board engagement face 108, located at the top of body 102 between vacuum connection side 104 and rail engagement side 106. Vacuum connection side 104 includes a connection port 110 to which a vacuum line (not shown) is attached. The vacuum line provides a vacuum to suction assembly 100 to operate suction assembly 100. While connection port 110 is shown as being disposed opposite rail engagement side 106, those skilled in the art will recognize that connection port 110 can be located on other sides, such as the bottom face (not shown) of suction assembly 100.

Rail engagement side 106 can include a magnetic face 112 such that rail engagement side 106 is magnetically attached to support rail 66. Each suction assembly 100 can be manually attached to suction support rail 66 and support rail 64 and manually adjusted for the length of board 50. Board engagement face 108 can include a ridge 114 that extends parallel to a leading edge 52 and a trailing edge 54 of board to engage either leading edge 52 or trailing edge 54 and ensure that board 50 is properly aligned on machine 60. Alternatively, instead of ridge 114, a line or other indicia can be applied to board engagement face 108 to assist a technician in aligning suction assembly 100 to its proper location for a particular board 50.

Board engagement face 108 also includes a plurality of suction cups 120 that are used to engage board 50 and secure board 50 to suction assembly 100. While three suction cups 120 are shown in FIG. 3, those skilled in the art will recognize that more or less than three suction cups 120 can be used. Suction cups 120 are aligned in a straight array and are no more than about 4 mm in diameter to take advantage of the printed circuit board industry standard which provides for a border of about 5 mm around the outside edges of just about all printed circuit boards. For extremely small boards in which the standard border is not available, break-away tabs (not shown) can be provided on at least one edge of the board to provide perimeter support around the board during manufacture. After manufacture, the break-away tabs can be removed from the board.

Each suction cup 120 is in fluid communication with connection port 110 as shown in FIG. 3 such that, when a vacuum is applied to suction assembly 100 through connection port 110, the vacuum is drawn through each of suction cups 120. In a non-vacuum condition, each suction cup 120 extends outward and above body 102. In an exemplary embodiment, suction cups 120 include bellows 122 that can extend and retract axially, as will be explained in detail later herein. As shown in FIG. 3, each bellows 122 has at least one rib 124 to assist in the extension and retraction. Suction cups 120 engage edges of board 50 and suck board onto cups 120, thereby “flattening” board 50.

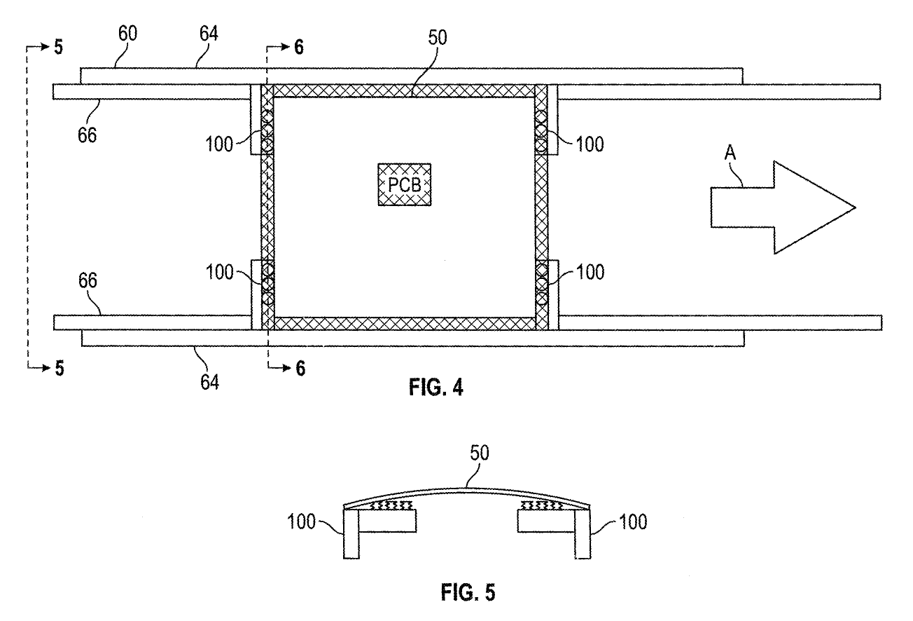

In operation, referring to FIGS. 2 and 4, a board 50 that is representative in size to a plurality of boards 50 that will be run through board assembly machine 60 in the direction of arrow “A” is used to set the spacing of suction assemblies 100 around the perimeter of board 50. Suction assemblies 100 are placed on board assembly machine 60 so that magnetic face 112 engages board support 62 and so that leading edge 52 and trailing edge 54 of board engage ridges 114 on respective suction assemblies 100.

In a production run, boards 50 are advanced to the work location on board assembly machine 60 by a conveyor (not shown) in a known manner. When leading edge 52 and trailing edge 54 of board 50 are located over suction cups 120 of suction assemblies 100, as shown in FIG. 5, board 50 can be bowed upward.

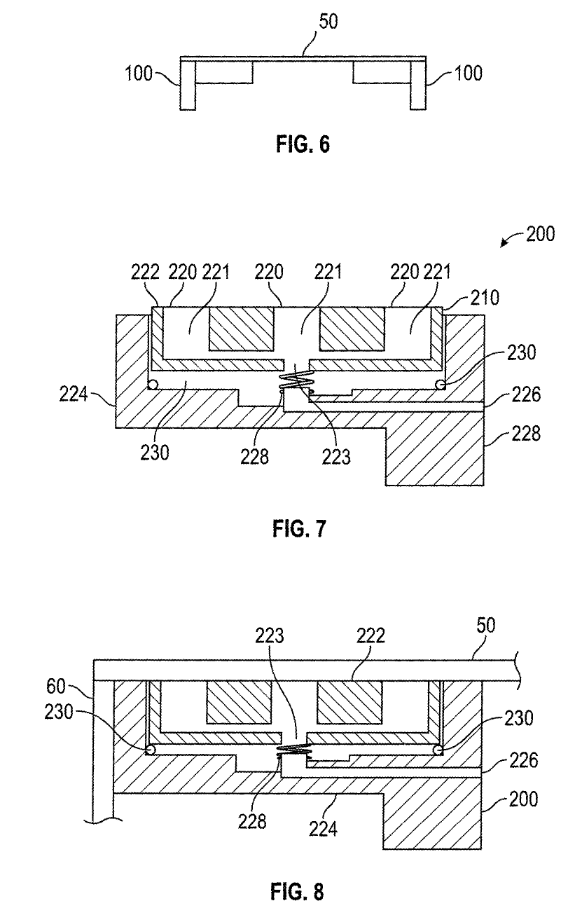

When board assembly machine 60 detects the presence of board 50 over suction cups 120, such as by an integrally mounted camera, board assembly machine 60 transmits an electronic signal to the vacuum device to apply a vacuum to suction assemblies 100. The vacuum drawn by the vacuum device through suction cups 120 is sufficient to draw board 50 downward to engage suction cups 120. Further application of the vacuum collapses bellows 122 such that suction cups 120 do not extend upwardly past board engagement face 108, thereby flattening board 50, as shown in FIG. 6, such that board 50 extends in a flat plane.

If the board support device 62 shown in FIG. 1 is used with board assembly machine 60, upon receiving an electronic signal from the vacuum source that the vacuum is drawing board 50 into the flattened position, the vacuum source can transmit an electronic signal to board assembly machine 60 to activate the board support device 62.

After board assembly machine 60 performs its operation on board 50, board assembly machine 60 transmits an electronic signal to the vacuum device to cease the vacuum, thereby releasing board 50 from suction cups 120 and allowing board 50 to be transported downstream in the direction of arrow “A” for additional processing.

In an alternative embodiment of a suction assembly 200, shown in FIG. 7, instead of suction cups 120 with collapsible bellows 122, a suction manifold assembly 210 can be used. Suction manifold assembly 210 can include a plurality of suction cups 220 that are mounted in a floating cup mount 222. Each suction cup 220 includes a through-passage 221 extending through cup mount 222 and in fluid communication with a cup mount port 223.

Cup mount 222 is movably retained in a receiver 224 so that cup mount 222 can move vertically with respect to receiver 224. Receiver 224 includes a vacuum port 226 located at a side 228 of receiver 224 and extending through receiver 224. Vacuum port 226 is in fluid communication with a vacuum source (not shown). Receiver 224 further includes a reservoir 230 into which cup mount 222 is inserted. When cup mount 222 is inserted into receiver 224, vacuum port 226 is axially aligned with cup mount port 223 so that, when a vacuum is applied to cup mount 222 through vacuum port 226, the vacuum is drawn through cup mount port 223 and through-passages 221. At least one biasing member 228 is located in cup mount 222 and biases suction manifold assembly 210 upward, away from receiver 224 so that cup mount 222 extends outwardly from receiver 224.

A sealing member, such as an o-ring 230, can be located within receiver 224 to form a seal between receiver 224 and cup mount 222 when a vacuum is applied to

When board 50 is in position on board assembly machine 60, board assembly machine 60 transmits an electronic signal to the vacuum source to draw a vacuum. The vacuum must be sufficient to overcome biasing member 228 to pull cup mount 222 downward into receiver 224 and engage o-ring 230, as shown in FIG. 8, forming a seal between cup mount 222 and receiver 224 and providing a direct fluid communication between vacuum port 226 and cup mount port 223.

After board assembly machine 60 performs its operation on board 50, board assembly machine 60 transmits an electronic signal to the vacuum device to cease the vacuum, thereby releasing board 50 from suction cups 220 and allowing board 50 to be transported downstream in the direction of arrow “A” for additional processing.

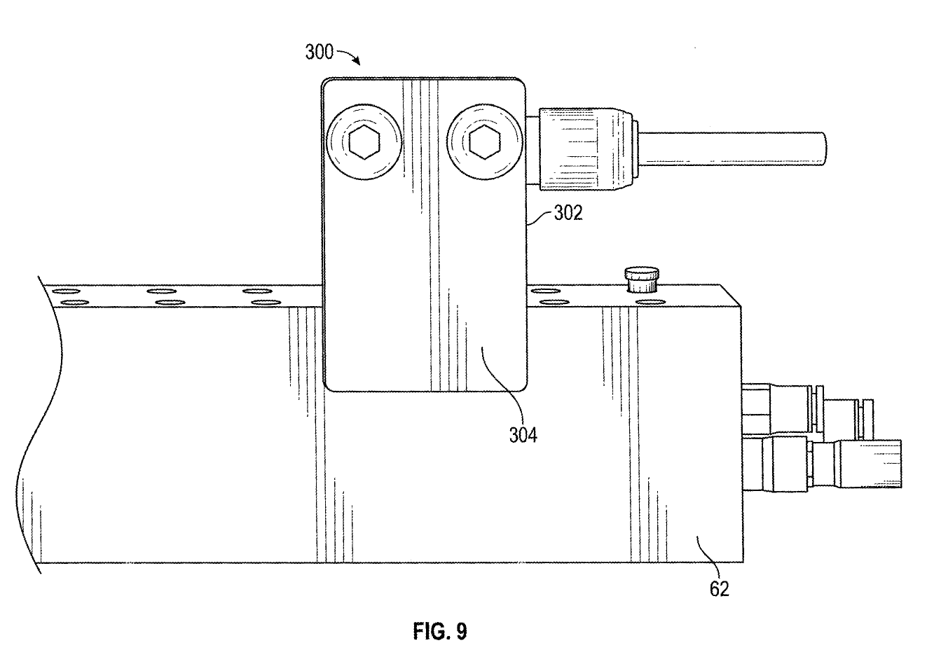

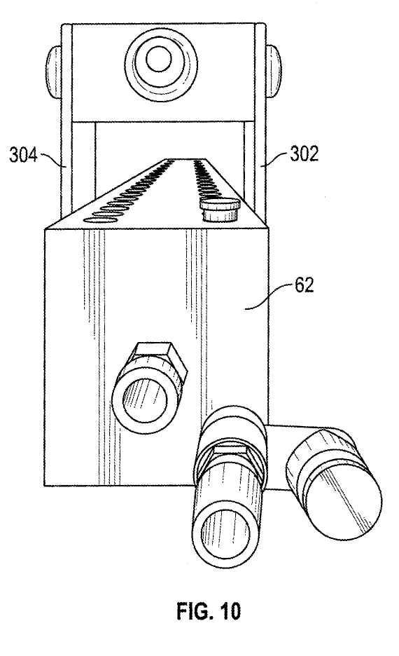

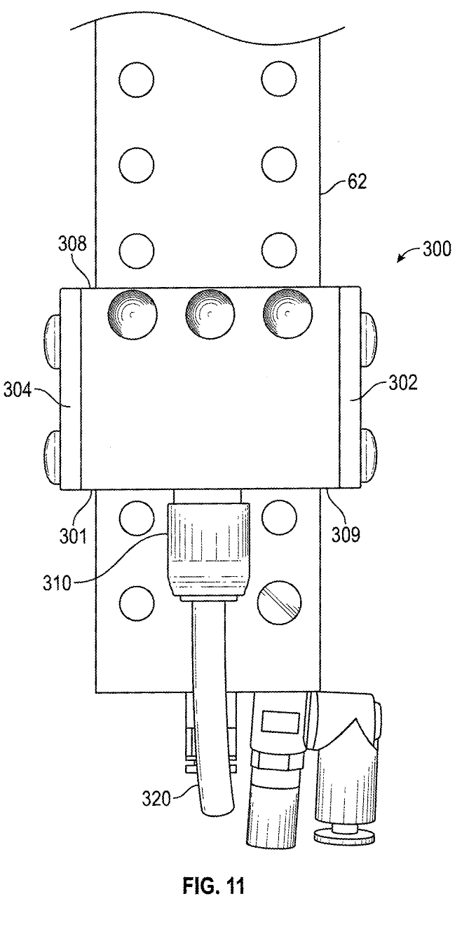

Referring now to FIGS. 9-11, an alternative embodiment of a suction assembly 300 according to the present invention is shown. Assembly 300 is mounted over board support 62. Assembly 300 includes side walls 302, 304 that straddle either side of board support 62 and mount assembly 300 over the top of board support 62.

First sidewall 302 extends downwardly from a body 301. Second sidewall 304 is located opposite first sidewall 302 and also extends downwardly from body 301. A board engagement face 308 is disposed on a top surface of body 301 between first sidewall 302 and second sidewall 304. A vacuum face 309 extends between first sidewall 302 and second sidewall 304. Vacuum face 309 includes a vacuum connection 310 for connecting a vacuum line 320 to apply vacuum to assembly 300. Operation of assembly 300 can be the same as the operation of either assembly 100 and/or assembly 200. Further, those skilled in the art will recognize that assemblies 100, 200 can be mounted on a board assembly machine 60 in other configurations as well.

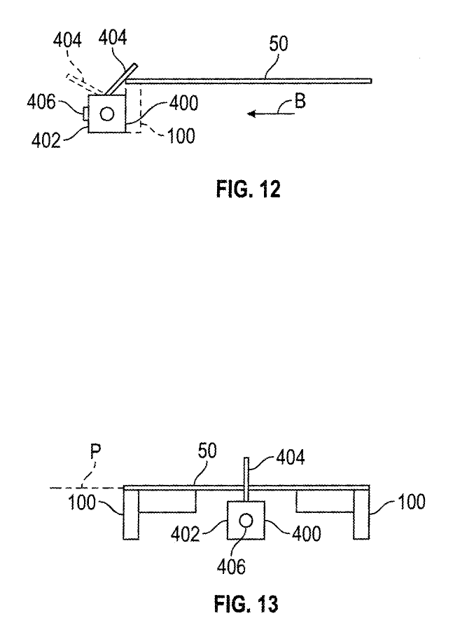

Referring now to FIGS. 12 and 13, a board flattener 400 according to an exemplary embodiment of the present invention is shown. Because a board 50 can become at least slightly warped during processing, resulting in board 50 becoming non-planar, with a convex curvature that extends generally orthogonally relative to the direction of movement of board 50 along board assembly machine 60, board flattener 400 is used to ensure that board 50 is flattened from the convex curvature into a flat plane so that any one of assemblies 100, 200, 300 can engage board 50 and secure board 50 along a plane “P”.

Board flattener 400 includes a base 402 that supports a pivoting arm 404. Pivoting arm 404 is movable between a board engaging position, as shown in the solid lines of FIG. 12, and a board movement position, as shown in the dashed lines of FIG. 12. As board 50 approaches assemblies 100, the front center edge of board 50 engages arm 404, pushing board 50 downward from the front center edge, thereby flattening board 50 to assist assemblies 100, 200, 300 to grip and secure board 50 for processing.

After board 50 is secured by assemblies 100, 200, 300, arm 404 pivots to the position shown in dashed lines in FIG. 12 so that, after board 50 is processed, board 50 can travel along the direction “B” shown in FIG. 12, over board flattener 400, and past board flattener 400 for further processing.

Board flattener 400 can be operated electrically, pneumatically, or by other means of operation known to those skilled in the art. A pneumatic connection 406 can extend from base 402 for connection of a pneumatic air line (not shown). A pneumatic/vacuum sensor (not shown) attached to assembly 100 can indicate when assembly 100 has gripped board 50, triggering operation of arm 404 from the board engaging position to the board movement position. After board 50 has passed over board flattener 400, a board positioning sensor, or other sensor (not shown) can indicate that a new board 50 is approaching board flattener 400, triggering operation of arm 404 from the board movement position to the board engaging position. The process is then repeated for subsequent boards 50.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

What is claimed is:

1. A circuit board suction assembly device comprising:
a body having:
a vacuum connection side;
a rail engagement side, disposed opposite the vacuum connection side; and
a board engagement face disposed between the vacuum connection side and a rail engagement side, wherein the board engagement face comprises at least one suction cup extending outwardly therefrom.

2. The circuit board suction assembly device according to claim 1, wherein the rail engagement side comprises a magnetic face.

3. The circuit board suction assembly device according to claim 1, wherein the board engagement face comprises a ridge extending between the vacuum connection side and the rail engagement side.

4. The circuit board suction assembly device according to claim 3, wherein the at least one suction cup comprises a plurality of suction cups extending along a first side of the ridge.

5. The circuit board suction assembly device according to claim 1, wherein the vacuum connection side comprises a connection port.

6. The circuit board suction assembly device according to claim 5, wherein the at least one suction cup is in fluid communication with the connection port.

7. The circuit board suction assembly device according to claim 1, wherein the board engagement face comprises a receiver, and wherein the at least one suction cup comprises a manifold disposed in the receiver, the manifold being vertically movable with respect to the receiver.

8. The circuit board suction assembly device according to claim 7, further comprising a biasing member disposed between the manifold and the receiver, the biasing member biasing the manifold vertically upward away from the receiver.

9. The circuit board suction assembly device according to claim 1, further comprising:
the first body disposed on a first side of a board assembly machine; a second body disposed on a second side of the board assembly machine; and
a board flattener disposed between the first body and the second body, the board flattener comprising:
a base;
an arm pivotally connected to the base between a board engaging position wherein the arm engages the board and a board movement position wherein the arm is disengaged from the board, allowing the board to be transported away from the circuit board suction assembly device.

10. The circuit board suction assembly device according to claim 9, wherein the board flattener further comprises a sensor adapted to sense a board approaching the board flattener and triggering operation of the arm from the board movement position to the board engaging position.

11. A circuit board suction assembly device comprising:
a body having:
a first sidewall extending downwardly from the body;
a second sidewall, opposite the first sidewall, the second sidewall extending outwardly from the body;
a board engagement face disposed on a top surface of the body between the first sidewall and the second sidewall, wherein the board engagement face comprises at least one suction cup extending outwardly therefrom; and
a vacuum face disposed between the first sidewall and the second sidewall.

12. The circuit board suction assembly device according to claim 11, wherein the second sidewall is disposed away from the first sidewall a sufficient distance such that the body extends over a board support.

13. The circuit board suction assembly device according to claim 11, wherein the vacuum face comprises a vacuum channel in fluid communication with the at least one suction cup.

14. A method of releasably securing a circuit board to board assembly machine comprising the steps of:
(a) installing the circuit board suction assembly device according to claim 1 onto a board assembly machine;
(b) using the board assembly machine to advance a board to the circuit board suction assembly device; and
(c) applying a vacuum to the at least one suction cup, the at least one suction cup engaging the board and drawing the board downward against the board engagement face.

15. The method according to claim 15, wherein the board engagement face comprises a ridge and wherein, during step (c), the board engages the ridge.

16. The method according to claim 15, wherein, during step (c), the at least one suction cup retracts below the board engagement face.

17. The method according to claim 15, further comprising the steps of:
(d) performing an operation on the board;
(e) removing the vacuum from the at least one suction cup;
(f) transporting the board away from the circuit board suction assembly device; and
(g) repeating steps (a)-(f).

18. The method according to claim 14, further comprising providing a board flattener disposed between the first body and the second body, the board flattener comprising:
a base;
an arm pivotally connected to the base between a board engaging position wherein the arm engages the board and a board movement position wherein the arm is disengaged from the board, allowing the board to be transported away from the circuit board suction assembly device;
the method further comprising the step of, between steps (b) and (c), pivoting the arm to the board engaging position.

19. The method according claim 18, further comprising, after step (c), pivoting the arm to the board movement position.
